(19) United States
(12) Patent Application Publication
(10) Pub. No.: US 2026/0015768 A1
(43) Pub. Date: Jan. 15, 2026

(54) MAGNET RAMP PROFILES DURING SINGLE CRYSTAL SILICON GROWTH

(71) Applicant: GlobalWafers Co., Ltd., Hsinchu (TW)

(72) Inventors: Zheng Lu, O'Fallon, MO (US); Sumeet S. Bhagavat, St. Charles, MO (US)

(21) Appl. No.: 19/258,170

(22) Filed: Jul. 2, 2025

Related U.S. Application Data
(60) Provisional application No. 63/669,537, filed on Jul. 10, 2024.
(60) Provisional application No. 63/729,570, filed on Dec. 9, 2024.

(51) Int. Cl. C30B 30/04; C30B 15/20; C30B 29/06

(52) U.S. Cl. CPC C30B 30/04; C30B 15/20; C30B 29/06

(57) ABSTRACT

Control of magnet ramp profiles with predetermined ramp rates in Czochralski silicon crystal growth to mitigate the transient behavior in silicon melt flow and its impact to semiconductor silicon crystal growth and crystal quality. The magnetic field strength may be regulated in at least two stages or at least three stages of growth of the constant diameter portion of the ingot.

### CROSS-REFERENCE TO RELATED APPLICATIONS

This application claims the benefit of U.S. Provisional Patent Application No. 63/669,537, filed Jul. 10, 2024, and claims the benefit of U.S. Provisional Patent Application No. 63/729,570, filed Dec. 9, 2024. Both applications are incorporated herein by reference in their entirety.

### TECHNICAL FIELD

The field of disclosure relates to a process of using magnet ramp profiles with predetermined ramp rates in Czochralski silicon crystal growth to mitigate the transient behavior in silicon melt flow and its impact to semiconductor silicon crystal growth and crystal quality.

### BACKGROUND

During Czochralski silicon crystal growth, various growth conditions change at different stages of growth which can induce transient melt flow behaviors. These transient flows may cause significant and negative impacts to the crystal growth process and impact crystal quality. This phenomenon is pronounced in crystal growth with horizontal magnets and at relatively strong magnetic field strengths.

Application of a magnetic field during silicon crystal growth reduces convective flow turbulence and suppresses growth striations which can cause various issues in downstream wafer quality if not controlled effectively. The magnetic field also controls melt oxygen during crystal growth. The use of horizontal magnets (HMCZ) provides high efficiencies in all these applications which makes HMCZ the dominant configuration in advanced silicon crystal growth applications. Transient flow behaviors caused by use of a horizontal magnet are more pronounced compared to that of the traditional cusp configuration. As shown in FIGS. 4 and 5, the crystal diameter and the pull rate in the early body growth of the ingot significantly fluctuate, at least in part due to the transient melt flow created by the increase of horizontal magnetic field strength in the early body.

A need exists for an effective method to mitigate transient melt flow behavior and its impact on crystal growth.

This section is intended to introduce the reader to various aspects of art that may be related to various aspects of the disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### SUMMARY

One aspect of the present disclosure is directed to a method for reducing transient melt behavior during growth of a single crystal silicon ingot. Polycrystalline silicon is melted in a crucible enclosed in a growth chamber to form a melt. The melt has a melt surface. A seed crystal is contacted with the melt. The seed crystal is withdrawn from the melt to form the silicon ingot. A horizontal magnetic field is applied to the melt during formation of a constant diameter portion of the silicon ingot. The horizontal magnetic field is applied by a pair of magnetic coils. The pair of magnetic coils are characterized by a maximum magnetic field strength that the pair of magnetic coils is capable of applying to the melt. A magnetic field strength is regulated during formation of the constant diameter portion of the silicon ingot in at least three stages of ingot growth. The constant diameter portion has a length. The at least three stages include a first stage, second stage and third stage. The first stage corresponds to formation of the silicon ingot from a beginning of formation of the constant diameter portion of the silicon ingot up to a first intermediate ingot length. The second stage corresponds to formation of the silicon ingot from at least the first intermediate ingot length to a second intermediate ingot length. The third stage corresponds to formation of the silicon ingot from at least the second intermediate ingot length to a third intermediate ingot length. Regulating the magnetic field strength includes ramping the magnetic field strength from an initial magnetic field strength to a first intermediate magnetic field strength during the first stage. The magnetic field strength is maintained at a second stage magnetic field strength during the second stage. The second stage magnetic field strength is between 75% and 125% of the first intermediate field strength. The magnetic field strength is ramped from the second stage magnetic field strength to a second intermediate magnetic field strength during the third stage.

Another aspect of the present disclosure is directed to a method for reducing transient melt behavior during growth of a single crystal silicon ingot. Polycrystalline silicon is melted in a crucible enclosed in a growth chamber to form a melt. The melt has a melt surface. A seed crystal is contacted with the melt. The seed crystal is withdrawn from the melt to form the silicon ingot. A horizontal magnetic field is applied to the melt during formation of a constant diameter portion of the silicon ingot. The horizontal magnetic field is applied by a pair of magnetic coils. The pair of magnetic coils is characterized by a maximum magnetic field strength that the pair of magnetic coils is capable of applying to the melt. A magnetic field strength is regulated during formation of the constant diameter portion of the silicon ingot in at least two stages of ingot growth. The constant diameter portion has a length. The at least two stages include a first stage and a second stage. The first stage corresponds to formation of the silicon ingot from a beginning of formation of the constant diameter portion of the silicon ingot up to a first intermediate ingot length. The second stage corresponds to formation of the silicon ingot from at least the first intermediate ingot length to a total length of the constant diameter portion of the silicon ingot. Regulating the magnetic field strength includes ramping the magnetic field strength from an initial magnetic field strength to a first intermediate magnetic field strength during the first stage. The magnetic field strength is ramped from the initial magnetic field strength to the first intermediate magnetic field strength in no more than 20% of the length of the constant diameter portion. The magnetic field strength is maintained at a second stage magnetic field strength during the second stage. The second stage magnetic field strength is between 75% and 125% of the first intermediate magnetic field strength.

Various refinements exist of the features noted in relation to the above-mentioned aspects of the present disclosure. Further features may also be incorporated in the above-mentioned aspects of the present disclosure as well. These refinements and additional features may exist individually or in any combination. For instance, various features discussed below in relation to any of the illustrated embodiments of the present disclosure may be incorporated into any of the above-described aspects of the present disclosure, alone or in any combination.

### BRIEF DESCRIPTION OF THE DRAWINGS

FIG. 1 is a cross-section view of a HMCZ ingot puller apparatus before silicon ingot growth.

FIG. 2 is a cross-section view of the HMCZ ingot puller apparatus of FIG. 1 during silicon ingot growth.

FIG. 3 is a schematic diagram illustrating a magnetic field applied to a crucible containing a melt in an ingot puller apparatus.

FIG. 4 shows example diameter profiles during silicon crystal body growth.

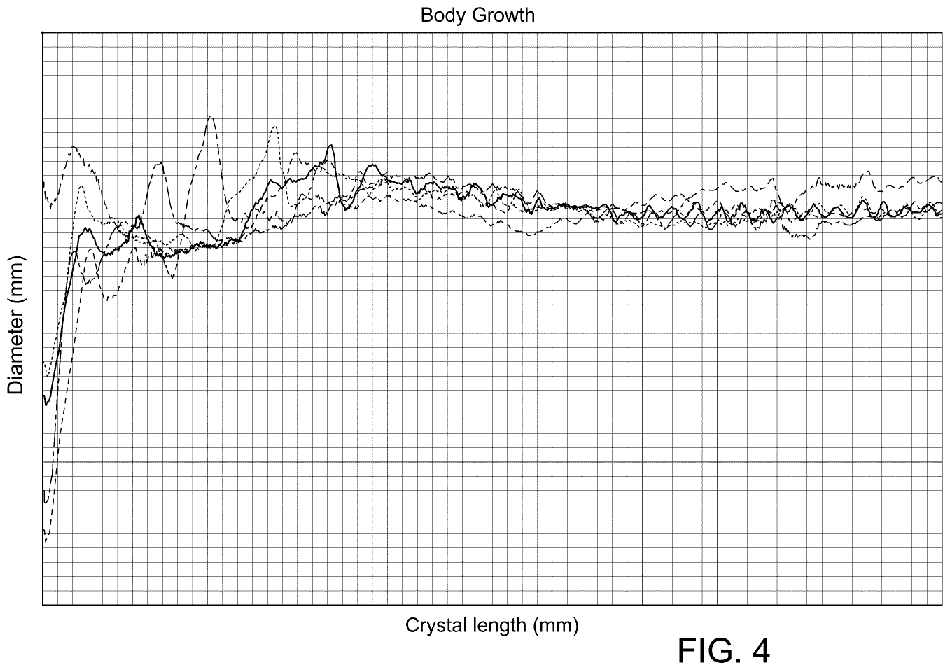

FIG. 5 shows example pull rate profiles during silicon crystal body growth.

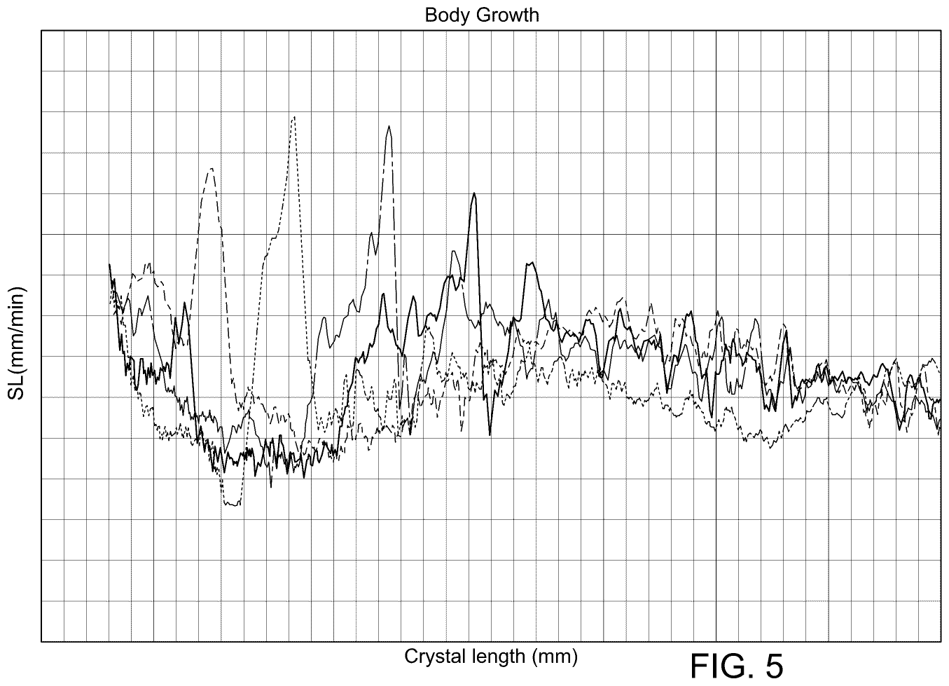

FIG. 6 shows correlation of pull rate fluctuations to ramping profiles of the magnetic field strength during silicon crystal body growth.

FIG. 7 shows correlation of diameter fluctuations to ramping profiles of the magnetic field strength during silicon crystal body growth.

FIG. 8 shows an example in which the longer ramp profile (shown as dashed line) which induces significant transient flow in undesired ingot locations is replaced with two ramp profiles (shown as solid line) each with 10 times the original ramp rate and 1/20 of the original duration.

FIG. 9 shows an example in which the longer ramp profile (shown as dashed line) which induces significant transient flow in undesired ingot location is replaced with a ramp profile (shown as solid line) with 20 times the original ramp rate and 1/20 of the original duration.

Corresponding reference characters indicate corresponding parts throughout the drawings.

### DETAILED DESCRIPTION

Provisions of the present disclosure relate to use of predetermined ramp rate profiles during growth of silicon ingots by the Czochralski process to reduce the transient melt flow behavior of the silicon melt. Ramp rate profiles may be selected which move the peak of the transient to either earlier part or later part of the body growth (e.g., depending on the requirements of the specific crystal processes).

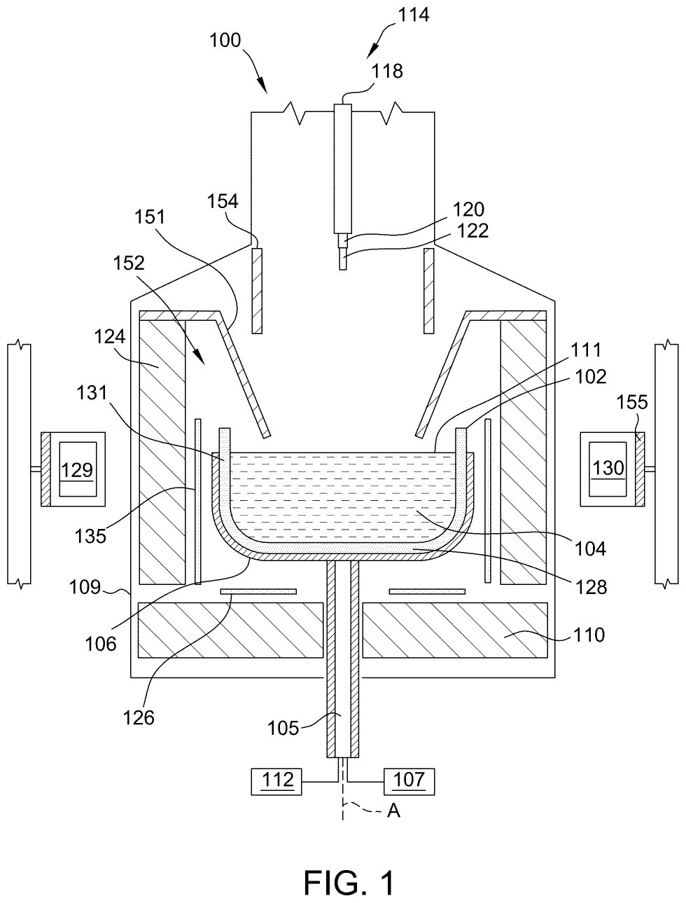

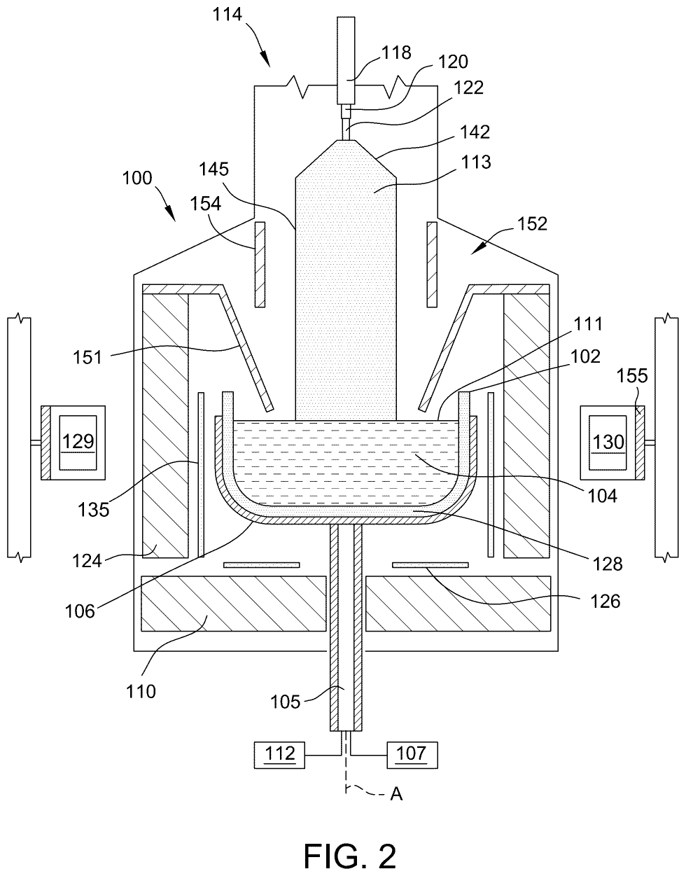

The methods of the present disclosure may generally be carried out in any ingot puller apparatus that is configured to pull a single crystal silicon ingot and in which a horizontal magnetic field is applied to the melt. An example ingot puller apparatus (or more simply “ingot puller”) is indicated generally a “100” in FIG. 1. The ingot puller apparatus 100 includes a crucible 102 for holding a melt 104 of semiconductor or solar-grade material, such as silicon, supported by a susceptor 106. The ingot puller apparatus 100 includes a crystal puller housing 109 that defines a growth chamber 152 for pulling a silicon ingot 113 (FIG. 2) from the melt 104 along a pull axis A.

The crucible 102 includes a floor 128 and a sidewall 131 that extends upward from the floor 128. The sidewall 131 is generally vertical. Within the crucible 102 is a silicon melt 104 having a melt surface 111.

In some embodiments, the crucible 102 is layered. For example, the crucible 102 may be made of a quartz base layer and a synthetic quartz liner disposed on the quartz base layer.

The susceptor 106 is supported by a shaft 105. The susceptor 106, crucible 102, shaft 105 and ingot 113 (FIG. 2) have a common longitudinal axis A or “pull axis” A.

A pulling mechanism 114 is provided within the ingot puller apparatus 100 for growing and pulling an ingot 113 from the melt 104. Pulling mechanism 114 includes a pulling cable 118, a seed holder or chuck 120 coupled to one end of the pulling cable 118, and a silicon seed crystal 122 coupled to the seed holder or chuck 120 for initiating crystal growth. One end of the pulling cable 118 is connected to a pulley (not shown) or a drum (not shown), or any other suitable type of lifting mechanism, for example, a shaft, and the other end is connected to the chuck 120 that holds the seed crystal 122. In operation, the seed crystal 122 is lowered to contact the melt 104. The pulling mechanism 114 is operated to cause the seed crystal 122 to rise. This causes a single crystal ingot 113 (FIG. 2) to be withdrawn from the melt 104.

During heating and crystal pulling, a crucible drive unit 107 (e.g., a motor) rotates the crucible 102 and susceptor 106. A lift mechanism 112 raises and lowers the crucible 102 along the pull axis A during the growth process. For example, the crucible 102 may be at a lowest position (near the bottom heater 126) in which an initial charge of solid-phase polycrystalline silicon previously added to the crucible 102 is melted. Crystal growth commences by contacting the melt 104 with the seed crystal 122 and lifting the seed crystal 122 by the pulling mechanism 114. As the ingot grows (i.e., formation of neck, crown and constant diameter portion), the silicon melt 104 is consumed and the height of the melt in the crucible 102 decreases. The crucible 102 and susceptor 106 may be raised to maintain the melt surface 111 at or near the same position relative to the ingot puller apparatus 100 (FIG. 2).

A crystal drive unit (not shown) may also rotate the pulling cable 118 and ingot 113 (FIG. 2) in a direction opposite the direction in which the crucible drive unit 107 rotates the crucible 102 (e.g., counter-rotation). In embodiments using iso-rotation, the crystal drive unit may rotate the pulling cable 118 in the same direction in which crucible drive unit 107 rotates the crucible 102. In addition, the crystal drive unit raises and lowers the ingot 113 relative to the melt surface 111 as desired during the growth process.

The ingot puller apparatus 100 may include an inert gas system to introduce and withdraw an inert gas such as argon from the growth chamber 152. The ingot puller apparatus 100 may also include a dopant feed system (not shown) for introducing dopant into the melt 104.

According to the Czochralski single crystal growth process, a quantity of polycrystalline silicon, or polysilicon, is charged to the crucible 102. The initial semiconductor or solar-grade material that is introduced into the crucible is melted by heat provided from one or more heating elements to form a silicon melt in the crucible. The ingot puller apparatus 100 includes bottom insulation 110 and side insulation 124 to retain heat in the puller apparatus. In the illustrated embodiment, the ingot puller apparatus 100 includes a bottom heater 126 disposed below the crucible floor 128. The crucible 102 may be moved to be in relatively close proximity to the bottom heater 126 to melt the polycrystalline charged to the crucible 102.

To form the ingot, the seed crystal 122 is contacted with the surface 111 of the melt 104. The pulling mechanism 114 is operated to pull the seed crystal 122 from the melt 104. Referring now to FIG. 2, the ingot 113 includes a crown portion 142 in which the ingot transitions and tapers outward from the seed crystal 122 to reach a target diameter. The ingot 113 includes a constant diameter portion 145 or cylindrical “main body” of the crystal which is grown by increasing the pull rate. The main body 145 of the ingot 113 has a relatively constant diameter. The ingot 113 includes a tail or end-cone (not shown) in which the ingot tapers in diameter after the main body 145. When the diameter becomes small enough, the ingot 113 is then separated from the melt 104.

The ingot puller apparatus 100 is configured to produce a cylindrical semiconductor ingot having an ingot diameter of 150 mm, greater than 150 mm, more specifically in a range from approximately 150 mm to 450 mm, and even more specifically, a diameter of approximately 300 mm. In other embodiments, ingot puller apparatus 100 is configured to produce a semiconductor ingot having a 200 mm ingot diameter or a 450 mm ingot diameter. In addition, in one embodiment, the apparatus 100 is configured to produce a semiconductor ingot having a constant diameter portion with a total ingot length of at least 900 mm or more. In some embodiments, the system is configured to produce a semiconductor ingot having a constant diameter portion with a length of 1950 mm, 2250 mm, 2350 mm, or longer than 2350 mm. In some embodiments, the ingot puller apparatus 100 is configured to produce a semiconductor ingot having a constant diameter portion of at least 1200 mm, at least 1500 mm, at least 1750 mm or at least 1900 mm (e.g., 900 mm to 2500 mm, 1200 mm to 2350 mm or 1500 mm to 2250 mm).

The ingot puller apparatus 100 includes a side heater 135 and a susceptor 106 that encircles the crucible 102 to maintain the temperature of the melt 104 during crystal growth. The side heater 135 is disposed radially outward to the crucible sidewall 131 as the crucible 102 travels up and down the pull axis A. The side heater 135 and bottom heater 126 may be any type of heater that allows the side heater 135 and bottom heater 126 to operate as described herein. In some embodiments, the heaters 126, 135 are resistance heaters. The side heater 135 and bottom heater 126 may be controlled by a control system (not shown) so that the temperature of the melt 104 is controlled throughout the pulling process.

The ingot puller apparatus 100 may include a heat shield 151. The heat shield 151 may shroud the ingot 113 and may be disposed within the crucible 102 during crystal growth (FIG. 2). The ingot puller apparatus 100 may be cooled such as by circulating cooling fluid through an outer chamber of the apparatus. A cooling jacket 154 is disposed within the growth chamber 152 for cooling the ingot 113.

The crystal growth processes of the present disclosure may be batch processes in which solid silicon is initially added to the crucible 102 to form a silicon melt without additional solid-silicon being added to the crucible 102 during crystal growth. In other embodiments, the crystal growth processes in a continuous Czochralski process in which silicon is added to the crucible during ingot growth (e.g., with the crucible being divided into zones such as into melt and growth zones).

The ingot puller apparatus 100 of the present disclosure includes a pair of magnetic coils 129, 130 (FIG. 1) that generate a horizontal magnetic field during ingot growth (e.g., opposing magnetic coils). The magnetic coils 129, 130 are disposed radially outward from the crucible 102. In some embodiments, the apparatus 100 includes two pairs of opposing magnetic coils.

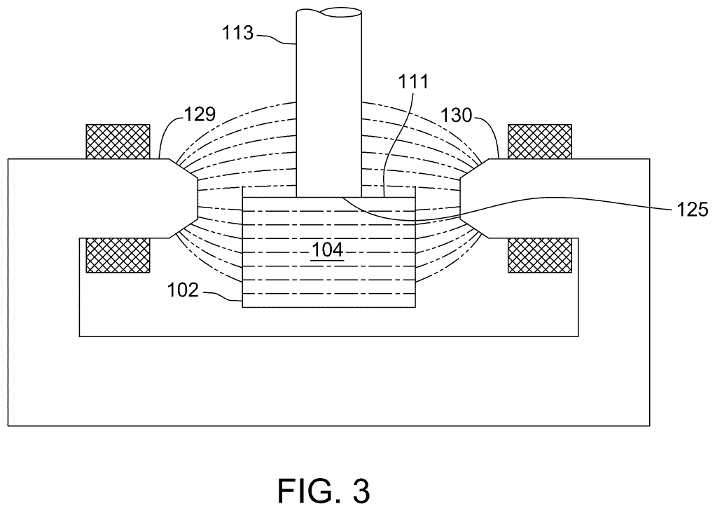

FIG. 3 is a diagram illustrating a horizontal magnetic field being applied to a crucible 102 containing a melt 104 from which an ingot 113 is grown. The transition between the melt and the ingot is generally referred to as the crystal-melt interface 125 (alternatively the “ingot-melt” or “solid-melt” interface) and is typically non-linear, for example concave, convex or gull-winged relative to the melt surface 111. The two magnetic coils 129, 130 are placed in opposition to generate a magnetic field generally perpendicular to the ingot-growth direction and generally parallel to the melt surface 111. The magnetic coils 129, 130 may be a conventional electromagnet, a superconductor electromagnet, or any other suitable magnetic for producing a horizontal magnetic field of the desired strength. Application of a horizontal magnetic field gives rise to Lorentz force along the axial direction, in a direction opposite of fluid motion, opposing forces driving melt convection. The convection in the melt is thus suppressed, and the axial temperature gradient in the ingot near the interface increases. The melt-ingot interface then moves upward to the ingot side to accommodate the increased axial temperature gradient in the ingot near the interface and the contribution from the melt convection in the crucible decreases. The horizontal configuration has the advantage of efficiency in damping a convective flow at the melt surface 111.

The magnetic coils 129, 130 may be cooled by circulating cooling fluid through the coils 129, 130. A ferrous shield 155 (FIG. 1) may surround the magnetic coils 129, 130 to reduce stray magnetic fields and to enhance the strength of the field produced.

The crucible 102 may be rotated in a direction opposite at which the ingot 113 is rotated with the crucible 102 being rotated at a rate in a range from 0.1 RPM to 5.0 RPM (i.e., −0.1 RPM to −5.0 RPM) or even from 0.1 RPM to 1.6 RPM (i.e., −0.1 RPM to −1.6 RPM) or from 0.1 RPM to 1.2 RPM (i.e., −0.1 RPM to −1.2 RPM). In other embodiments, the crucible 102 is rotated in the same direction at which the ingot 113 is rotated with the crucible 102 being rotated at a rate in a range from 0.1 RPM to 5.0 RPM, from 0.7 RPM to 5 RPM, or from 1.2 RPM to 5.0 RPM.

The magnetic coils 129, 130 may be operated at any power(s) that enables ingot growth to proceed consistent as described herein. The magnetic coils 129, 130 are characterized by a maximum magnetic field strength that the coils are capable of applying to the melt (e.g., at maximum power applied to the coils 129, 130). For example, the magnetic coils may be characterized by a maximum magnetic coil strength of at least 1000 gauss, at least 1500 gauss, at least 2500 gauss, less than 7500 gauss, less than 5000 gauss, less than 4000 gauss, or from 1000 gauss to 7500 gauss, 1000 gauss to 5000 gauss or 2000 gauss to 5000 gauss. Generally, the strength of the magnetic field is its magnitude at the center of the maximum gauss plane. The magnetic coils 129, 130 may apply a magnetic field strength ranging from 0% of the maximum magnetic field strength (i.e., the magnetic coils 129, 130 are not powered) to 100% of the maximum magnetic field strength.

In some embodiments of the present disclosure, during growth of the neck and crown of the ingot, no magnetic field is applied to the melt. In other embodiments, a magnetic field is applied during neck and/or crown growth (e.g., up to 20% of maximum magnetic field strength).

In accordance with embodiments of the present disclosure, the pair of magnetic coils 129, 130 apply a horizontal magnetic field to the melt during formation of a constant diameter portion 145 (FIG. 2) of the silicon ingot 113. In some embodiments of the present disclosure, the magnetic field strength is regulated during formation of the constant diameter portion of the silicon ingot in at least two stages of ingot growth. In other embodiments of the present disclosure, the magnetic field strength is regulated during formation of the constant diameter portion of the silicon ingot in at least three stages of ingot growth.

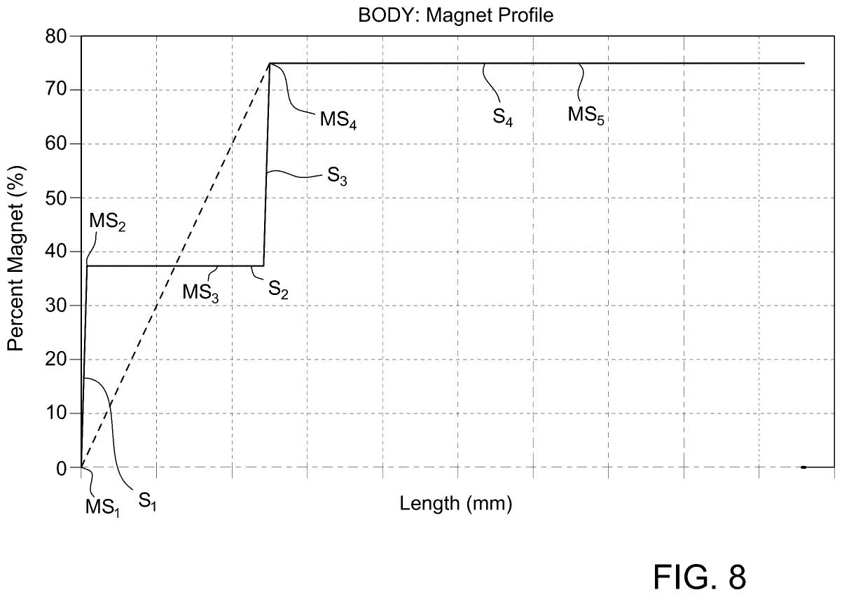

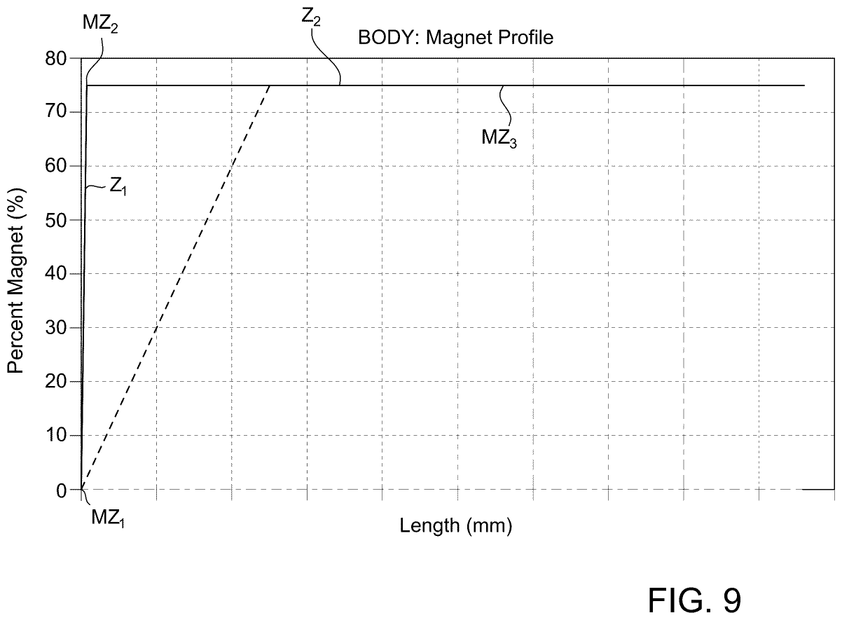

Two example profiles of the magnetic field strength ramp rate are shown in FIGS. 8-9. In the first profile (shown as solid line in FIG. 8), the magnetic field strength is regulated during formation of the constant diameter portion of the silicon ingot in at least three stages of ingot growth. In the second profile (shown as solid line in FIG. 9), the magnetic field strength is regulated during formation of the constant diameter portion of the silicon ingot in at least two stages of ingot growth.

In the first profile (FIG. 8), the magnetic field strength is regulated in a first stage S₁ that corresponds to formation of the silicon ingot from the beginning of formation of the constant diameter portion of the silicon ingot up to a first intermediate ingot length and a second stage S₂ that corresponds to formation of the silicon ingot from at least the first intermediate ingot length to a second intermediate ingot length. The first profile also includes a third stage S₃ corresponding to formation of the silicon ingot from at least the second intermediate ingot length to a third intermediate ingot length. In some embodiments, the at least three stages includes a fourth stage S₄ corresponding to formation of the silicon ingot from at least the third intermediate ingot length to a total length of the constant diameter portion of the ingot.

As shown in FIG. 8, in the first profile, regulating the magnetic field strength includes ramping the magnetic field strength from an initial magnetic field strength MS₁ to a first intermediate magnetic field strength MS: during the first stage S₁. The magnetic field strength is maintained at a second stage magnetic field strength MS₃ during the second stage S₂. The second stage magnetic field strength MS₃ may be between 75% and 125% of the first intermediate field strength MS₂. In the third stage S₃, the magnetic field strength ramps from the second stage magnetic field strength MS₃ to a second intermediate magnetic field strength MS₄ during the third stage S₃. In some embodiments in which the profile has a fourth stage S₄ (FIG. 8), the magnetic field strength is maintained at a third stage magnetic field strength MS₅ during the fourth stage S₄, the third stage magnetic field strength MS₅ being between 75% and 125% of the second intermediate field strength MS₄.

In some embodiments, the initial magnetic field strength MS₁ is 0% of the maximum magnetic field strength (i.e., no power is applied to the magnetic coils 129, 130 such that no magnetic field is generated). In other embodiments, the initial magnetic field strength MS₁ is 0% to 20% of the maximum magnetic field strength or even 0% to 10% of the maximum magnetic field strength.

In the first step S₁, the magnetic field strength is ramped from the initial magnetic field strength MS₁ to the first intermediate magnetic field strength MS₂, such as in less than 20% of the length of the constant diameter portion. In other embodiments, the magnetic field strength is ramped from the initial magnetic field strength MS₁ to the first intermediate magnetic field strength MS₂ in less than 10% of the length of the constant diameter portion or, as in other embodiments, less than 5%, or less than 2.5%, from 0.5% to 20%, from 0.5% to 10%, or from 1% to 10% of the length of the constant diameter portion. The first intermediate magnetic field strength MS: may be at least 25% of the maximum magnetic field strength or, as in other embodiments, at least 30%, at least 35%, from 25% to 60%, from 30% to 60% or from 30% to 50% of the maximum magnetic field strength.

In the second step S₂ in which the magnetic field strength is maintained at the second stage magnetic field strength MS₃, in some embodiments, the length of the second stage S₂ is no more than 30% of the length of the constant diameter portion. In other embodiments, the length of the second stage S₂ is no more than 25%, no more than 20%, or no more than 10% of the length of the constant diameter portion of the ingot. The second stage magnetic field strength MS₃ may be at least 25% of the maximum magnetic field strength or, as in other embodiments, at least 30%, at least 35%, from 25% to 60%, from 30% to 60% or from 30% to 50% of the maximum magnetic field strength.

As shown in FIG. 8, the magnetic field strength is ramped from the second stage magnetic field strength MS₃ to the second intermediate magnetic field strength MS₄ in less than 20% of the length of the constant diameter portion of the ingot. In other embodiments, the magnetic field strength is ramped from the second stage magnetic field strength MS₃ to the second intermediate magnetic field strength MS₄ in less than 10% of the length of the constant diameter portion of the ingot or less than 5%, or less than 2.5%, from 0.5% to 20%, from 0.5% to 10%, or from 1% to 10% of the length of the constant diameter portion of the ingot. As shown in FIG. 8, in the first profile, the third stage S₃ terminates within the first 50% of the length of the constant diameter portion 145 (FIG. 2) of the ingot. In other embodiments, the third stage S₃ terminates within the first 40%, the first 25%, the first 20% or the first 10% of the length of the constant diameter portion. The second intermediate magnetic field strength MS₄ to which the magnetic field strength is ramped in the third stage S₃ may be at least 60% of the maximum magnetic field strength. In other embodiments, the second intermediate magnetic field strength MS₄ is at least 65%, at least 70%, from 60% to 100%, from 70% to 100% or from 65% to 95% of the maximum magnetic field strength.

As shown in FIG. 8, in the fourth step S₄, the third stage magnetic field strength MS₅ may be at least 1.25 times the second stage magnetic field strength MS₃ or, as in other embodiments, at least 1.5 times, at least 1.6 times, at least 1.75 times, at least 1.9 times, at least 2.0 times, from 1.25 times to 2.5 times or 1.5 times to 2.0 times the second stage magnetic field strength MS₃. The third stage magnetic field strength MS₅ may be at least 60% of the maximum magnetic field strength, or at least 65%, at least 70%, from 60% to 100%, from 70% to 100% or from 65% to 95% of the maximum magnetic field strength.

In the second profile shown in FIG. 9 in which the magnetic field strength is regulated during formation of the constant diameter portion of the silicon ingot in at least two stages of ingot growth, the magnetic field strength is regulated in a first stage Z₁ that corresponds to formation of the silicon ingot from the beginning of formation of the constant diameter portion of the silicon ingot up to a first intermediate ingot length and a second stage S: that corresponds to formation of the silicon ingot from at least the first intermediate ingot length to a total length of the constant diameter portion of the silicon ingot.

As shown in FIG. 9, in the second profile, regulating the magnetic field strength includes ramping the magnetic field strength from an initial magnetic field strength MZ₁ to a first intermediate magnetic field strength MZ₂ during the first stage Z₁. As shown in FIG. 9, the magnetic field strength is ramped from the initial magnetic field strength MZ₁ to the first intermediate magnetic field strength MZ₂ in no more than 20% of the length of the constant diameter portion. In other embodiments, the magnetic field strength is ramped from the initial magnetic field strength MZ₁ to the first intermediate magnetic field strength MZ₂ in no more than 15%, or no more than 10%, no more than 5%, from 0.5% to 20%, from 0.5% to 15%, from 0.5% to 10% or 0.5% to 5% of the length of the constant diameter portion. The initial magnetic field strength MZ₁ may be 0% of the maximum magnetic field strength or, as in other embodiments, 0% to 20% of the maximum magnetic field strength, or 0% to 10% of the maximum magnetic field strength.

During the second stage Z₂, the magnetic field strength is maintained at a second stage magnetic field strength MZ₃ with the second stage magnetic field strength MZ₃ being between 75% and 125% of the first intermediate field strength. The second stage magnetic field strength MZ₃ may be at least 60% of the maximum magnetic field strength, or at least 65%, at least 70%, from 60% to 100%, from 70% to 100% or from 65% to 95% of the maximum magnetic field strength.

In various embodiments (alone or in combination with other ramp parameters described herein), the ramp profiles of magnetic field strength may be completed within the first 0 to 400 mm of body length (i.e., the constant diameter portion), 0 to 300 mm of body length, 0 to 200 mm of body length, 0 to 100 mm of body length, 0 to 50 of mm body length, 0 to 25 mm of body length, or 0 to 5 mm of body length. Fluctuations of the diameter and the fluctuations of the pull rate caused by the transient melt flow created by the ramping magnetic field strength may be limited within 0 to 400 mm body length, 0 to 300 mm body length, 0 to 200 mm body length, 0 to 100 mm body length, 0 to 50 mm body length, 0 to 25 mm, 0 to 5 mm body length.

Compared to conventional methods for growing a single crystal silicon ingot, the methods of the present disclosure have several advantages. The position of the transient behavior in silicon melt flow may be moved by moving both the start and the end of the ramp of magnetic field. The maximum amplitude of the transient may be reduced by reducing the ramp rate of the magnetic field strength. The duration of the transient may be reduced by increasing the ramp rate of the magnetic field strength. By controlling the ramp rate, the duration of the transient may be reduced and the transient may be moved to a location that normally would not be used as prime product due to other reasons, or the amplitude of the transient may be reduced by applying a longer ramp with a lower ramp rate or multiple ramps with lower ramp rates may be used (or combinations for these approaches).

### EXAMPLES

The processes of the present disclosure are further illustrated by the following Examples. These Examples should not be viewed in a limiting sense.

### Example 1: Transient Melt Flow Impact on Crystal Diameter and Pull Rate Fluctuations

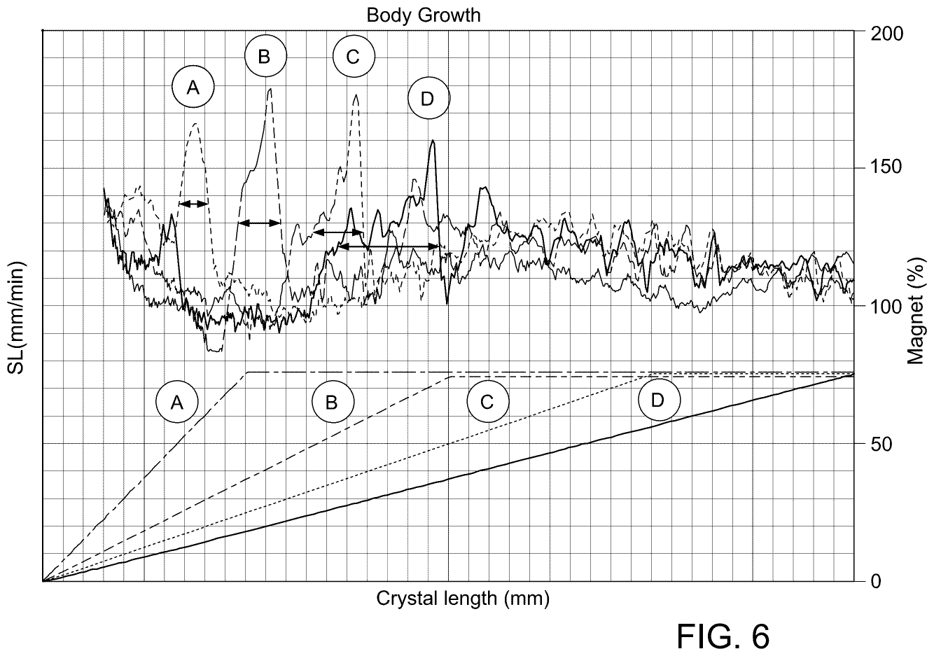

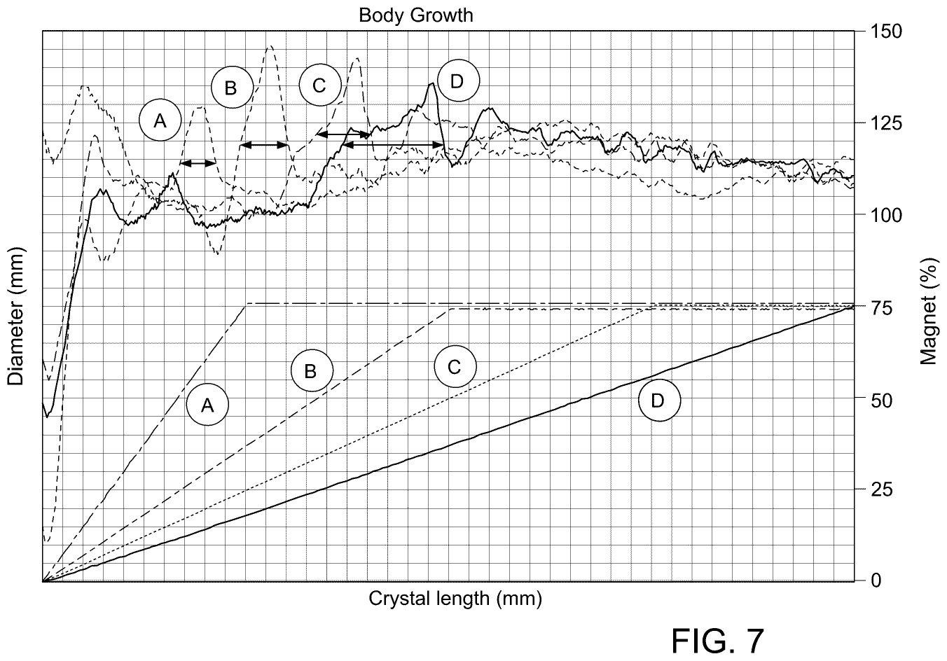

FIGS. 6-7 show correlations between fluctuations in diameter profiles and crystal pull rate profiles caused by transient melt flow and the ramp profiles of the horizontal magnetic field strength. As shown in the magnetic field strength profiles in FIGS. 6-7, “A,” “B,” “C,” and “D” are intentionally arranged magnet profiles that result from various preselected ramp rates (i.e., different ramp durations).

As shown in the pull rate profiles in FIG. 6, the resulted pull rate fluctuations have locations, amplitudes and durations well correlated to that of the ramp profiles of the magnetic field strength. Ramping the magnetic field profile faster moves the diameter fluctuations to earlier in the body length. Higher magnet ramp rates increase the amplitudes of the diameter fluctuations. Longer magnet ramping durations increase the durations of the diameter fluctuations.

Similarly, as shown in the diameter profiles in FIG. 7, the resulting diameter fluctuations caused by the magnet ramp profiles have locations, amplitudes and durations well correlated to that of the ramping profiles of the magnetic field strength. Ramping the magnetic field profile faster moves the diameter fluctuations to earlier in the body length. Higher magnet ramp rates increase the amplitudes of the diameter fluctuations. Longer magnet ramp durations increase the durations of the diameter fluctuations.

As used herein, the terms “about,” “substantially,” “essentially” and “approximately” when used in conjunction with ranges of dimensions, concentrations, temperatures or other physical or chemical properties or characteristics is meant to cover variations that may exist in the upper and/or lower limits of the ranges of the properties or characteristics, including, for example, variations resulting from rounding, measurement methodology or other statistical variation.

When introducing elements of the present disclosure or the embodiment(s) thereof, the articles “a,” “an,” “the,” and “said” are intended to mean that there are one or more of the elements. The terms “comprising,” “including,” “containing,” and “having” are intended to be inclusive and mean that there may be additional elements other than the listed elements. The use of terms indicating a particular orientation (e.g., “top,” “bottom,” “side,” etc.) is for convenience of description and does not require any particular orientation of the item described.

As various changes could be made in the above constructions and methods without departing from the scope of the disclosure, it is intended that all matter contained in the above description and shown in the accompanying drawing[s] shall be interpreted as illustrative and not in a limiting sense.

What is claimed is:

1. A method for reducing transient melt behavior during growth of a single crystal silicon ingot, the method comprising:
melting polycrystalline silicon in a crucible enclosed in a growth chamber to form a melt, the melt having a melt surface;
contacting a seed crystal with the melt;
withdrawing the seed crystal from the melt to form the silicon ingot;
applying a horizontal magnetic field to the melt during formation of a constant diameter portion of the silicon ingot, the horizontal magnetic field being applied by a pair of magnetic coils, the pair of magnetic coils being characterized by a maximum magnetic field strength that the pair of magnetic coils is capable of applying to the melt;
regulating a magnetic field strength during formation of the constant diameter portion of the silicon ingot in at least three stages of ingot growth, the constant diameter portion having a length, the at least three stages comprising:
a first stage corresponding to formation of the silicon ingot from a beginning of formation of the constant diameter portion of the silicon ingot up to a first intermediate ingot length;
a second stage corresponding to formation of the silicon ingot from at least the first intermediate ingot length to a second intermediate ingot length;
a third stage corresponding to formation of the silicon ingot from at least the second intermediate ingot length to a third intermediate ingot length;
wherein regulating the magnetic field strength comprises:
ramping the magnetic field strength from an initial magnetic field strength to a first intermediate magnetic field strength during the first stage;
maintaining the magnetic field strength at a second stage magnetic field strength during the second stage, the second stage magnetic field strength being between 75% and 125% of the first intermediate field strength; and
ramping the magnetic field strength from the second stage magnetic field strength to a second intermediate magnetic field strength during the third stage.

2. The method as set forth in claim 1 wherein the third stage terminates within the first 50% of the length of the constant diameter portion.

3. The method as set forth in claim 1 wherein the at least three stages comprises a fourth stage corresponding to formation of the silicon ingot from at least the third intermediate ingot length to a total length of the constant diameter portion of the ingot, the method comprising maintaining the magnetic field strength at a third stage magnetic field strength during the fourth stage, the third stage magnetic field strength being between 75% and 125% of the second intermediate field strength.

4. The method as set forth in claim 3 wherein third stage magnetic field strength is at least 60% of the maximum magnetic field strength.

5. The method as set forth in claim 3 wherein the third stage magnetic field strength is at least 1.25 times the second stage magnetic field strength.

6. The method as set forth in claim 1 wherein the initial magnetic field strength is 0% to 20% of the maximum magnetic field strength.

7. The method as set forth in claim 1 wherein second stage magnetic field strength is at least 25% of the maximum magnetic field strength.

8. The method as set forth in claim 1 wherein first intermediate magnetic field strength is at least 25% of the maximum magnetic field strength, or at least 30%, at least 35%, from 25% to 60%, from 30% to 60% or from 30% to 50% of the maximum magnetic field strength.

9. The method as set forth in claim 1 wherein second intermediate magnetic field strength is at least 60% of the maximum magnetic field strength.

10. The method as set forth in claim 1 wherein the magnetic field strength is ramped from the initial magnetic field strength to a first intermediate magnetic field strength in less than 5% of the length of the constant diameter portion.

11. The method as set forth in claim 1 wherein the magnetic field strength is ramped from the second stage magnetic field strength to a second intermediate magnetic field strength in less than 5% of the length of the constant diameter portion.

12. The method as set forth in claim 1 wherein the length of the second stage is no more than 10% of the length of the constant diameter portion.

13. The method as set forth in claim 1 wherein the horizontal magnetic field is applied to the melt by a single pair of magnetic coils, the maximum magnetic field strength that the pair of magnetic coils is capable of applying to the melt being the maximum magnetic field strength that the single pair of magnetic coils is capable of applying to the melt.

14. The method as set forth in claim 1 wherein the horizontal magnetic field is applied to the melt by two pairs of magnetic coils, the maximum magnetic field strength that the pair of magnetic coils is capable of applying to the melt being the maximum magnetic field strength that the two pairs of magnetic coils are capable of applying to the melt.

15. A method for reducing transient melt behavior during growth of a single crystal silicon ingot, the method comprising:
melting polycrystalline silicon in a crucible enclosed in a growth chamber to form a melt, the melt having a melt surface;
contacting a seed crystal with the melt;
withdrawing the seed crystal from the melt to form the silicon ingot;
applying a horizontal magnetic field to the melt during formation of a constant diameter portion of the silicon ingot, the horizontal magnetic field being applied by a pair of magnetic coils, the pair of magnetic coils being characterized by a maximum magnetic field strength that the pair of magnetic coils is capable of applying to the melt;
regulating a magnetic field strength during formation of the constant diameter portion of the silicon ingot in at least two stages of ingot growth, the constant diameter portion having a length, the at least two stages comprising:
a first stage corresponding to formation of the silicon ingot from a beginning of formation of the constant diameter portion of the silicon ingot up to a first intermediate ingot length; and
a second stage corresponding to formation of the silicon ingot from at least the first intermediate ingot length to a total length of the constant diameter portion of the silicon ingot;
wherein regulating the magnetic field strength comprises:
ramping the magnetic field strength from an initial magnetic field strength to a first intermediate magnetic field strength during the first stage, wherein the magnetic field strength is ramped from the initial magnetic field strength to the first intermediate magnetic field strength in no more than 20% of the length of the constant diameter portion; and
maintaining the magnetic field strength at a second stage magnetic field strength during the second stage, the second stage magnetic field strength being between 75% and 125% of the first intermediate magnetic field strength.

16. The method as set forth in claim 15 wherein the magnetic field strength is ramped from the initial magnetic field strength to the first intermediate magnetic field strength in no more than 5% of the length of the constant diameter portion.

17. The method as set forth in claim 15 wherein the second stage magnetic field strength is at least 70% of the maximum magnetic field strength.

18. The method as set forth in claim 15 wherein the initial magnetic field strength is 0% to 10% of the maximum magnetic field strength.

19. The method as set forth in claim 15 wherein the horizontal magnetic field is applied to the melt by a single pair of magnetic coils, the maximum magnetic field strength that the pair of magnetic coils is capable of applying to the melt being the maximum magnetic field strength that the single pair of magnetic coils is capable of applying to the melt.

20. The method as set forth in claim 15 wherein the horizontal magnetic field is applied to the melt by two pairs of magnetic coils, the maximum magnetic field strength that the pair of magnetic coils is capable of applying to the melt being the maximum magnetic field strength that the two pairs of magnetic coils are capable of applying to the melt.
